(19) United States
(12) Patent Application Publication
(10) Pub. No.: US 2022/0181885 A1
(43) Pub. Date: Jun. 9, 2022

(54) COMPONENT PLACEMENT FOR AN ENERGY GENERATION AND/OR STORAGE SYSTEM

(71) Applicant: Enphase Energy, Inc., Petaluma, CA (US)

(72) Inventors: Sarojit AUDDYA, Kolkata (IN); Garvit GOPAL, Uttar Pradesh (IN); Vidyasagar Venkata NALLAPATI, Bangalore (IN); Nishant AGARWAL, Uttar Pradesh (IN); Ashish BANSAL, Bengaluru (IN); Jayant SOMANI, Saratoga, CA (US); Sumit SARAOGI, Freemont, CA (US)

(21) Appl. No.: 17/542,742

(22) Filed: Dec. 6, 2021

Related U.S. Application Data
(60) Provisional application No. 63/122,728, filed on Dec. 8, 2020.

(51) Int. Cl. H02J 3/38; F24S 50/20

(52) U.S. Cl. CPC H02J 3/381; F24S 2201/00; H02J 2300/24; F24S 50/20

(57) ABSTRACT

A method, apparatus and user interface for component placement for components of a system including a solar energy generation system, an energy storage system or both. The method receives indicium of a location for installation of the system, receives indicium of energy requirements for the facility at the location, and retrieves at least one image comprising one or more of a roof view of the facility, a digital surface map containing the facility or an irradiance map of the facility. Based, at least in part, on one or more of the digital surface map or the irradiance map, determining locations for placement of components of the system, and rendering an image of the facility including the components positioned at the determined locations.

### RELATED APPLICATION

This application claims benefit to U.S. Provisional Patent Application Ser. No. 63/122,728 filed 8 Dec. 2020 entitled “Component Placement For An Energy Management And/Or Storage System,” which is hereby incorporated herein by reference in its entirety.

### BACKGROUND

### Field

Embodiments of the present invention generally relate to energy generation and/or storage systems and, in particular, to a method and apparatus for placing components of such systems upon or within a facility associated with such systems.

### Description of the Related Art

A solar energy generation and storage system typically comprises a plurality of solar panels, one or more power inverters, a storage element and a service panel. The solar panels are arranged in an array and positioned to maximize solar exposure. Each solar panel or small groups of panels may be coupled to an inverter (so-called micro-inverters) or all the solar panels may be coupled to a single inverter. The inverter(s) convert the DC power produced by the solar panels into AC power. The AC power is coupled to the service panel for use by a facility (e.g., home or business), supplied to the power grid, and/or coupled to a storage element such that energy produced at one time is stored for use at a later time. Other energy generators having flexible capacity that is defined at installation include wind turbines arranged on a so-called wind farm. Storage elements may be one or more of batteries, fly wheels, hot fluid tank(s), hydrogen storage or the like. The most common storage element is a battery pack (i.e., a plurality of battery cells) having a bidirectional inverter coupled to the service panel to supply the batteries with DC power as well as allow the batteries to discharge through the inverter to supply AC power to the facility when needed.

Prospective purchasers of solar energy generation and storage systems typically begin the process by meeting with a system installer and having the installer perform a site survey. The installer manually estimates the capacity of the required system by visiting the site where the installation is planned, measuring the space available, estimating the capacity of the solar power generation available, and estimating the amount of energy storage that is commensurate with the amount of energy to be generated. Such meetings and surveys are time consuming and form an inefficient use of the purchaser's and installer's time. Especially when the prospective purchaser is merely exploring the possibility of making a purchase.

In some instances, a system may comprise only solar or only storage (i.e., storage in lieu of using a power generator during a black out). The process for estimating only solar system requirements or only storage system requirements is substantially similar to the inefficient process described above for estimating a solar and storage systems.

Therefore, there is a need for an efficient, automated technique for designing an energy generation and/or storage system and determining the placement of the energy generators and/or storage.

### BRIEF DESCRIPTION OF THE DRAWINGS

So that the manner in which the above recited features of the present invention can be understood in detail, a particular description of the invention, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a screen shot of an exemplary user interface of the component placement system in accordance with at least one embodiment of the invention;

FIG. 2 depicts a graphical output of storage device placement within a rendered image in accordance with at least one embodiment of the invention;

FIG. 3 depicts a block diagram of an energy generation and energy storage system in accordance with at least one embodiment of the invention;

FIG. 4 depicts a block diagram of a computer system used to create a component placement system in accordance with an embodiment of the invention;

FIG. 5 depicts a flow diagram of operation of the component placement system in accordance with at least one embodiment of the invention;

FIG. 6 depicts a flow diagram of a method for segmenting a roof in accordance with at least one embodiment of the invention;

FIGS. 7A, 7B, 7C together depict images used in performing the segmentation processing in accordance with at least one embodiment of the invention;

FIGS. 8A, 8B, 8C, 8D, 8E and 8F together depict images generated during the roof segmentation and obstruction detection process used in accordance with at least one embodiment of the invention;

FIG. 9 depicts a flow diagram of a method for positioning solar panels upon the roof that was segmented using the method of FIG. 6 in accordance with at least one embodiment of the invention;

FIG. 10 depicts a flow diagram of a method for orienting solar panels upon the roof that was segmented using the method of FIG. 6 in accordance with at least one embodiment of the invention;

FIG. 11 depicts images representing azimuth angle mapping in accordance with at least one embodiment of the invention;

FIG. 12 depicts a graphical representation of the azimuth angle mapping method of FIG. 10;

FIG. 13 depicts a flow diagram of a method for subsegmenting the roof that was segmented using solar flux data in accordance with at least one embodiment of the invention;

FIG. 14 depicts a flow diagram of a method for prioritizing the order of solar panel placement in accordance with at least one embodiment of the invention;

FIG. 15 depicts a flow diagram of a method for avoiding preplaced solar panels in accordance with at least one embodiment of the invention;

FIG. 16 graphically depicts images of solar panels being placed upon a roof using prioritized location method of FIG. 14;

FIG. 17 depicts a flow diagram of a method for rendering an image of the roof containing the solar panels in accordance with at least one embodiment of the invention;

FIG. 18 depicts an example of a facility image as rendered by the component placement system in accordance with at least one embodiment of the invention; and

FIG. 19 depicts a flow diagram of a method for rendering an image of a portion of a facility containing a storage system in accordance with at least one embodiment of the invention.

### DETAILED DESCRIPTION

Embodiments of the present invention comprise apparatus and methods for placing components of an energy generation and/or energy storage systems within and/or upon a facility (i.e., residential building or business building). Embodiments of the invention utilize a web page or mobile application as an interface to a user, i.e., a user interface. The interface facilitates data input such as facility energy use and facility location (e.g., physical address). In an embodiment for a component placement system for a solar energy generation system, from the energy use and location information, a component placement system may access one or more of: a roof image of the facility, a digital surface model (DSM) of the roof and an area surrounding the roof, solar azimuth angle data for segments of the roof and roof irradiance for the roof at the given address. The system segments the roof to create planar roof segments and analyzes the DSM to determine obstacles on the roof as well as determine the angle of the roof segments. Using the roof irradiance information, the system creates subsegments of the roof based on the irradiance level within segments. In addition, the energy use may be used to determine how many solar panels are necessary to generate the required amount of energy. From the azimuth angle data, the system determines the orientation for the solar panels in each subsegment and determines a placement location for each solar panel based on a prioritization schedule related to the amount of irradiance in each subsegment. The system then renders, within the user interface, an image of the facility with the solar panels placed upon the facility. The user has an opportunity to remove panels from location they do not wish panels to be located and the system recomputes the panel locations based upon the user's adjustment.

In another embodiment of the invention, the component placement system may be used to position energy storage components within a facility. Once the system has defined the amount of the storage required, the system places the system into a rendered image of the facility.

In the forgoing embodiments, the energy source is defined as an array of solar panels. In an alternative embodiment, the energy source may be an array of other resources or a combination of resources including, for example, wind turbines and the component placement system may use wind speed and wind direction data, rather than irradiance data, to define the positioning of a number of turbines and their energy capabilities necessary to meet a facility's requirements.

Embodiments of the component placement system solve the technical problem associated with automated design of energy generation and/or energy storage systems. Through the use of general-purpose computers programmed to operate as specific purpose computers with the specific purpose of utilizing information such as location data, roof layout, azimuth data, depth data, energy use at the location, and roof irradiance data to render an image of a facility integrated with placement of the components of an energy generation and/or energy storage system.

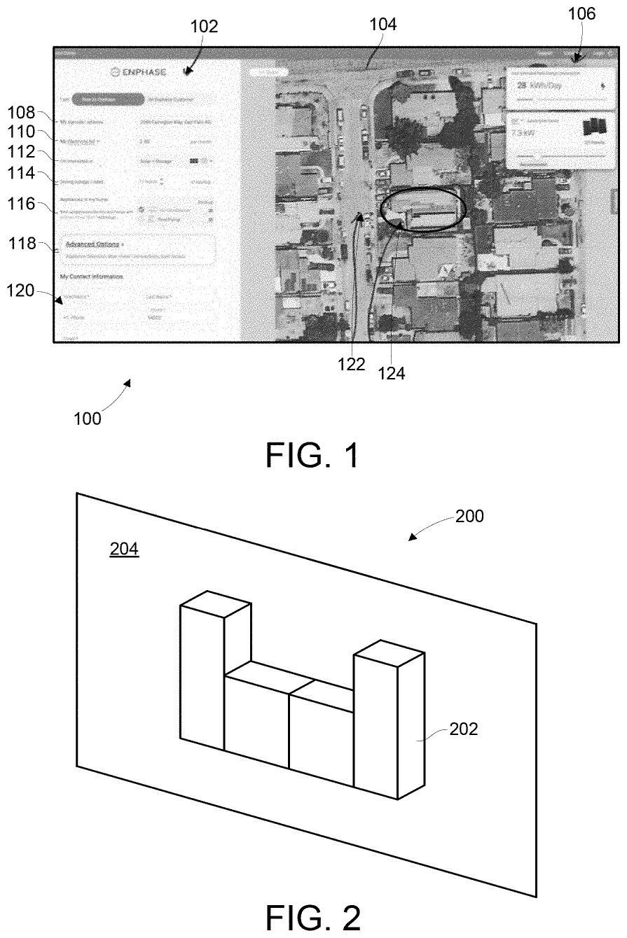

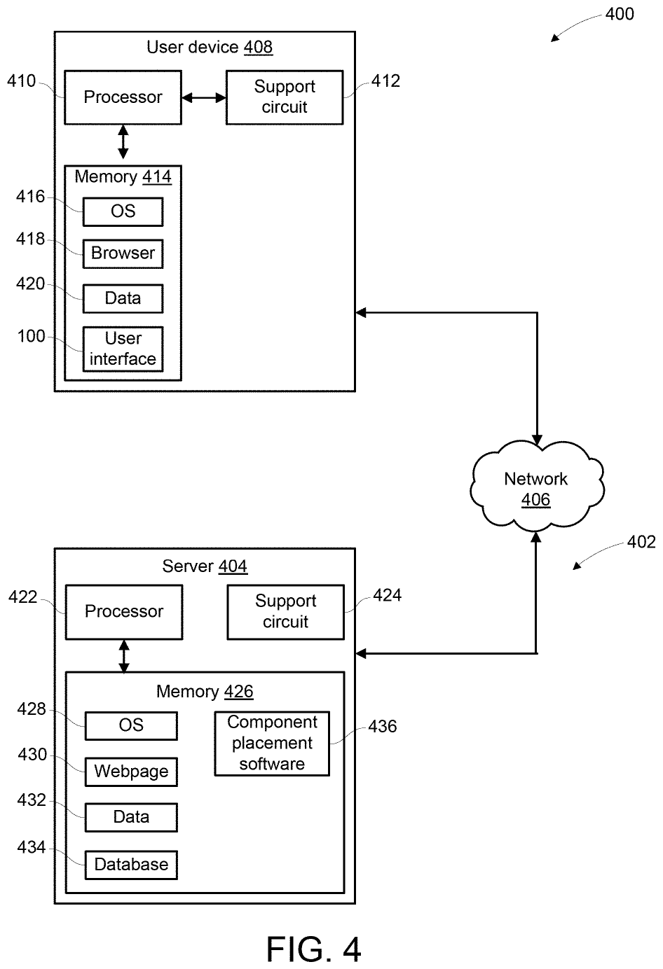

FIG. 1 depicts a screen shot 100 of an exemplary user interface of the component placement system (described below with respect to FIGS. 4 through 19 in accordance with at least one embodiment of the invention. The screen shot 100 comprises a user input region 102, a rendered image 104 of a facility at which the user is designing an energy generation and/or storage system, and a control region 106 wherein a user may make adjustments to the amount of energy stored or the amount of energy to generate (amount consumed). Within user input region 102, fields are presented in which the user enters one or more of: the facility address (field 108); the facility's energy consumption (field 110); type of system, i.e., solar, storage, or solar and storage (field 112); if storage is selected, the required duration of storage backup (field 114); and a field 116 where basic appliances can be selected and/or advanced options field 118 can be used to enter very specific appliances to more accurately define the backup required. Lastly, the user may enter contact information within field 120. The component placement system mostly uses two input parameters (1) the facility address and (2) the amount of energy consumed to determine the amount of energy needed to be generated and stored.

After entering, the address and energy requirement, the component placement system processes this information to render the facility 122 (residence or business) located at the address including a depiction of energy generators (in this case, solar panels 124) positioned on the roof of the facility. Within region 106, a user may adjust the amount of energy consumed/generated or the amount of energy stored using sliders. If an adjustment is made, the system redetermines the number and placement of solar panels. The user may also select solar panels (e.g., point and click) and have the image rendered again with a new placement of solar panels, avoiding the locations of the selected panels.

In addition, as depicted in FIG. 2, an additional embodiment renders a three-dimensional graphical view of the facility or portion of the facility 200 and integrates an image of the storage system (if any) 202 into the image. In this example, a wall 204 is rendered based upon a calculated height of the roof above ground (described in detail below). The image 200 includes a storage system image 202 mounted to the wall 204 that fits the specification entered into interface 100. The storage system 202 may comprise a number of individual storage units (cabinets) of varying sizes to fit the amount of requested storage. Such a rendered image 200 provides the user with an image of the storage system in context to facilitate an assessment of the aesthetics of the mounted system 202 and provide an estimate of the wall space consumed by the storage system 202.

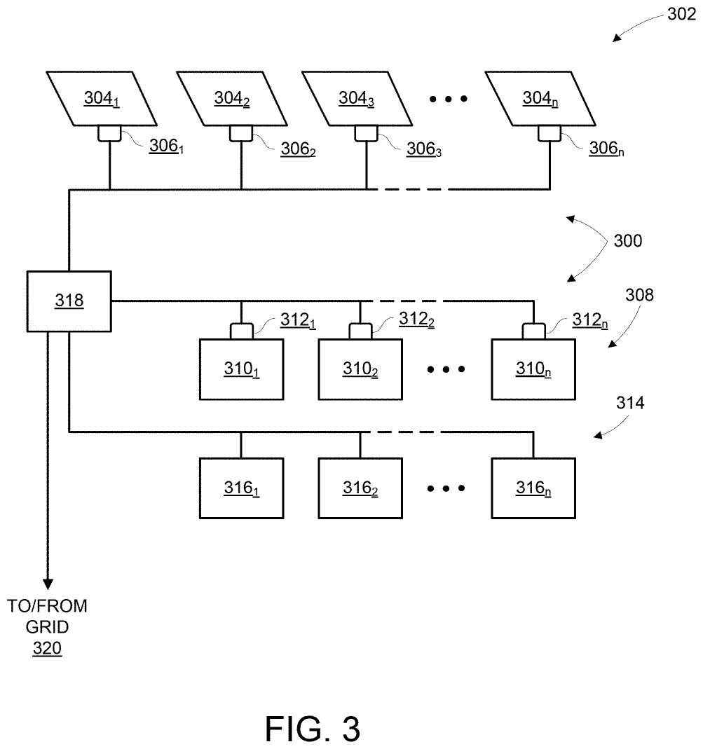

FIG. 3 depicts a block diagram of solar energy generation and storage system 300 having a components that are to be placed in accordance with at least one embodiment of the invention. The system 300 comprises a plurality of distributed generator 302 (e.g., solar panels 304₁, 304₂, 304₃, . . . 304ₙ coupled to inverters 306₁, 306₂, 306₃, . . . 306ₙ), storage 308 (e.g., batteries 310₁, 310₂, . . . 310ₙ coupled to bidirectional inverters 312₁, 312₂, . . . 312ₙ), and a service panel 318 through which the distributed generator 302 is coupled to the storage 308. The service panel 318 is also coupled to a plurality of loads 314 represented by loads 316₁, 316₂, . . . 316ₙ. The loads 314, in a residential application, may comprise washer, dryer, refrigerator, air conditioner, hot water heater, electric car, and/or any other electricity consuming device in the household. The loads 314, in an industrial application, may comprise electric motors, heating systems, air conditioning systems, refrigerators, freezers, and/or any other electricity consuming device generally used in an industrial setting. The service panel 318 may also be coupled to the power grid 320, such that, energy may be consumed from the grid 320 or sourced to the grid 320, as necessary. The service panel may include circuitry for controlling energy to the loads and or the storage devices. As shall be described below, embodiments of the present invention facilitate placing the distributed generators 302 and/or storage 308 within or upon the facility.

Although FIG. 3 depicts a distributed generator 302 having a single solar panel coupled to a single inverter (i.e., micro-inverter), this depiction is not meant to limit the scope of the invention. For example, embodiments of the invention may also be used with distributed generators having a plurality or more solar panels coupled to one or more inventers. The distributed generators 302 may also include solar panels coupled to DC optimizers and a single or small number of inverters coupled to the DC optimizers. Furthermore, distributed generators may include other forms of energy generation such as wind turbines arranged on a so-called “wind farm.” Similarly, energy storage in a battery-based storage system is described as an example of the type of storage whose capacity is estimated using embodiments of the invention; however, other forms of energy storage may be used such as fly wheel(s), hot fluid tank(s), hydrogen storage system(s), pressurized gas storage system(s), pumped storage hydropower, fuel cells, or the like.

FIG. 4 depicts a block diagram of a computer system 400 used to create a component placement system 402 for an energy generation and/or storage system in accordance with an embodiment of the invention. The computer system 400 comprises a server 404, a computer network 406 (e.g., Internet) and at least one user device 408 (e.g., mobile phone, digital assistant, computer, or any other device capable of displaying a web page). In operation, the user device 408 accesses a web page from the server 404 or launches an application (app) and displays the user interface (e.g., user interface 100 of FIG. 1) for user interaction. The server 404 and user device 408, when executing specific software, enables the general-purposes computers to operate as specific-purpose devices. Specifically, the server and user device together may operate as a component placement system 402 to determine placement of components and display the placement to a user on the user device 408 in response to user data entered into fields on the user interface 100.

The user device 408 comprises at least one processor 410, support circuits 412 and memory 414. The at least one processor 410 may be any form of processor or combination of processors including, but not limited to, central processing units, microprocessors, microcontrollers, field programmable gate arrays, graphics processing units, and the like. The support circuits 412 may comprise well-known circuits and devices facilitating functionality of the processor(s). The support circuits 412 may comprise one or more of, or a combination of, power supplies, clock circuits, communications circuits, cache, and/or the like.

The memory 414 comprises one or more forms of non-transitory computer readable media including one or more of, or any combination of, read-only memory or random-access memory. The memory 414 stores software and data including, for example, an operating system (OS) 416, a browser 418, data 410 and user interface software 100. The operating system 416 may be any form of operating system such as, for example, Apple iOS, Microsoft Windows, Apple macOS, Linux, Android or the like. The browser 418 may be any software that, when executed by the processor(s) 410, is capable of displaying and enabling user interaction with the user interface. Such browsers 418 include, but are not limited to, Explorer, Safari, Chrome, Edge, Firefox or the like. The data 420 may include a web page, or portion thereof, data used by a web page, data entered by a user into fields within a web page and/or any other data used by the browser 418 to display and facilitate use interaction with a web page. In lieu of using a web page to form the user interface 100, the user device may execute an application (an app) that performs the functions of the user interface 100.

The server 404 comprises at least one processor 422, support circuits 424 and memory 426. The at least one processor 422 may be any form of processor or combination of processors including, but not limited to, central processing units, microprocessors, microcontrollers, field programmable gate arrays, graphics processing units, and the like. The support circuits 424 may comprise well-known circuits and devices facilitating functionality of the processor(s). The support circuits 424 comprise one or more of, or a combination of, power supplies, clock circuits, communications circuits, cache, displays, and/or the like.

The memory 426 comprises one or more forms of non-transitory computer readable media including one or more of, or any combination of, read-only memory or random-access memory. The memory 426 stores software and data including, for example, an operating system (OS) 428, a web page 430, data 432, a database 434 and component placement software 436. The operating system 428 may be any form of operating system such as, for example, Apple iOS, Microsoft Windows, Apple macOS, Linux, Android or the like. The web page 430 is a web page that is accessible to the browser 418 of the at least one user device 408 to facilitate use of the component placement system 202 as shall be described in detail with respect to FIGS. 5 through 19 below. The data 420 may include data entered by a user into fields within a web page and/or any other data used by the server 404 to facilitate use of the web page. The database 434 contains data to facilitate determinations made by the component placement software 436. This data may include, but is not limited to, amount of irradiance corresponding to a location, amount of energy generated by specific numbers of solar panels, amount of energy capable of storage by specific storage devices, rooftop images, and the like. The database 434 may be locally stored at the server 404, may be remotely stored on another server or servers and accessed via the network 406, or may be a combination of local and remote storage of database information.

The server 404, when executing the component placement software 436, is transformed from a general-purpose device into a specific-purpose device. i.e., transformed into a portion of the component placement system 402. The component placement software 436, when executed, enables at least one user device 408 to access and interact with the web page 430. The access and interaction shall be described with respect to FIGS. 5 through 19.

FIG. 5 depicts a flow diagram of operation of a component placement system (402 of FIG. 4) for a solar energy generation and/or storage system (200 of FIG. 2) in accordance with an embodiment of the invention. As mentioned above, using the component placement system to position components of a solar energy system is a non-limiting example of a use for the system. The system may be used to position components of any energy generation system.

Each block of the flow diagrams below may represent a module of code to execute and/or combinations of hardware and/or software configured to perform one or more processes described herein. Though illustrated in a particular order, the following figures are not meant to be so limiting. Any number of blocks may proceed in any order (including being omitted) and/or substantially simultaneously (i.e., within technical tolerances of processors, etc.) to perform the operations described herein.

FIG. 5 depicts a method 500 that is performed when server 404 of FIG. 4 executes the component placement software 436. The method 500 begins at 502 and proceeds to 504 where a user, through the user device interacting with the user interface 100, enters an address of the facility where the energy generation system and/or energy storage system is to be located. Other than an address, a user may enter other indicium of location such as geographic coordinates, a code representing a location, lot/block numbers, or the like. The user also enters indicium of energy consumption at the facility (e.g., kWh per week/month/year). Typically, energy consumption may be determined from a monthly utility bill (e.g., cost) and the method 500 may compute the kWh use using standard or regional electricity rates. The indicium of energy use may also be an account number and login information for the facility's electricity utility such that the system may retrieve the energy consumption information.

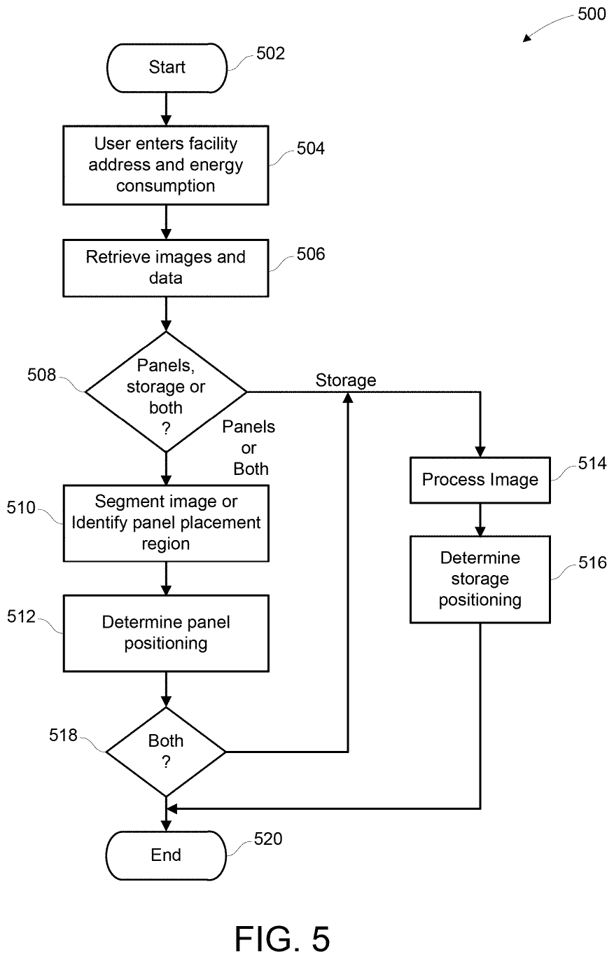

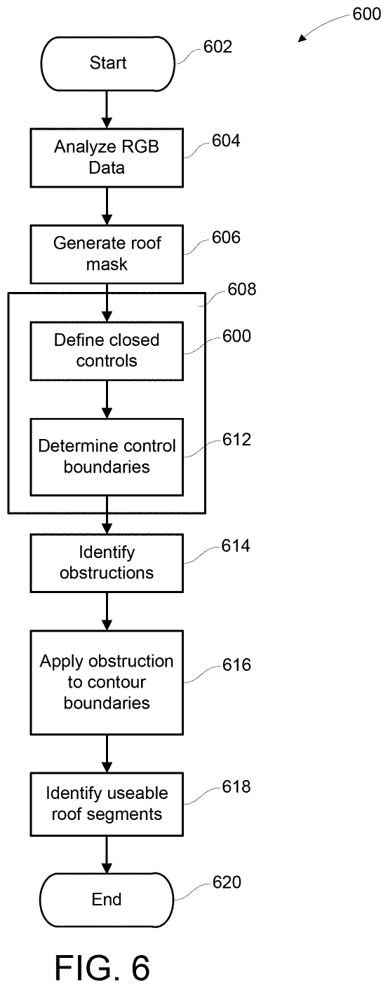

At 506, the method 500 retrieves images and data related to the facility location including, for example, an image of the facility roof (e.g., images captured by from satellite, drone or other aerial platform), irradiation data for the roof, solar azimuth angle data, a digital surface map (DSM) for the roof and area surrounding the facility, and the like. The aerial satellite data is generally produced as a virtual image from an elevation of about 50 meters. At 508, the method queries whether the user desires placement of solar panels, a storage system or both. If the user desires placement of solar panels, the method 500 proceeds from 510 to 512, where the method 500 segments the roof image to determine planar portions of the roof upon which solar panels can be positioned or is provided the identity of locations where on the roof the panels are to be positioned. Details of the segmentation process are provided below with reference to FIG. 6.

In one embodiment of the invention, segmentation may not be necessary. For example, a user could specifically locate where the panels are to be placed, e.g., by placing a graphical box around a roof region graphic or selecting specific roof portions where they desire the panels to be placed. In such an instance, the segmentation process would not be used and the system would immediately begin the process of placing the solar panels in the regions identified by the user.

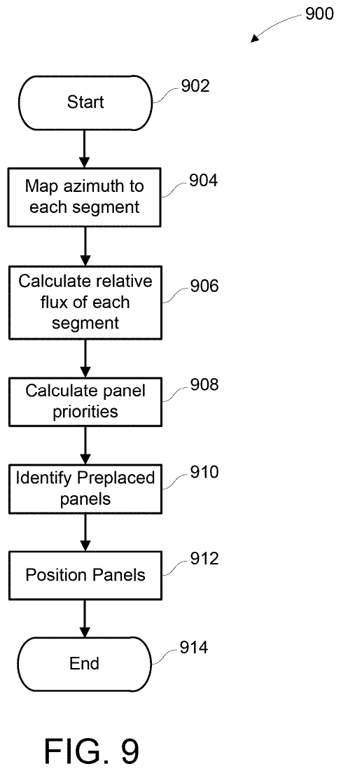

After segmentation, at 512, the method 500 determines the location for placement of each panel upon the roof and renders an image of the facility roof having the solar panels position thereon based, in part, on a prioritization schedule. Details of panel placement processing are provided below with reference to FIGS. 9 through 18.

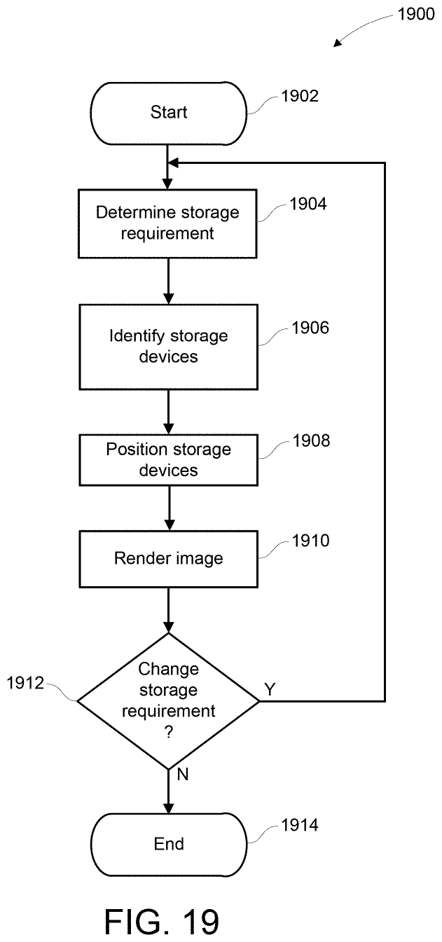

If the user selected “both” at 508, the method 500 proceeds from 518 to 514. Or, if the user selected only to place a storage system, the method 500 proceeds from 508 to 514. At 514, the method 500 processes a facility image to render walls beneath the roof that may be used to attach and retain the storage system. As described below with reference to FIG. 19, the walls may be rendered within a three-dimensional view of the facility or render a particular wall. At 518, the method 500 determines the amount of storage needed for the facility and renders a final image showing the storage devices positioned within the facility (e.g., positioned upon a wall). The method 500 ends at 520.

The following figures shall describe the details of the process of component placement.

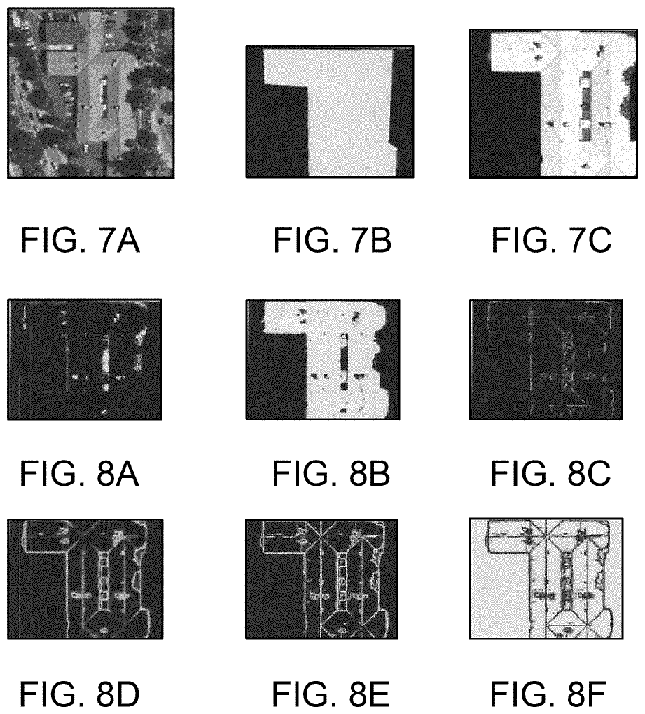

FIG. 6 depicts a flow diagram of the roof segmentation procedure performed at 508 in FIG. 5 (i.e., roof segmentation method 600) in accordance with at least one embodiment of the invention. Method 600 begins at 602 and proceeds to 604 where the RGB data (i.e., color images) is analyzed to facilitate segmenting the roof—identify roof slope, identify roof edges, and the like. At 606, a roof mask is generated for the roof image based on the RGB data analysis. The RGB data is used to determine the outer edges of the roof by identifying an abrupt change in pixel depth at the roof edges (i.e., a change in depth from the roof to the ground surrounding the roof). The pixels within the roof boundary form the roof mask. For example, FIG. 7A depicts a facility rooftop image (e.g., a red-blue-green (RGB) satellite image). FIG. 7B depicts a roof mask. In some embodiments, the roof mask may be provided by a data provider and would not require calculation.

The roof mask is used to extract the portion of the roof RGB data where solar panels can potentially be positioned. At 608, the portion of the roof image and RGB data within the mask is analyzed to determine roof segments (i.e., planar portions of the roof). FIG. 7C depicts the roof segments. To segment the roof, at 608, the method 600 performs a contour analysis of the roof image using the RGB data. At 610, the largest closed contours are found using a Canny algorithm and/or a HED (Holistically-Nested Edge Detection) algorithm to detect edges of each planar surface and, at 612, determine pixel coordinates of contour boundaries.

At 614, the method 600 identifies obstructions within each roof segment. An obstruction is defined as a portion of the roof upon which a solar panel cannot be mounted, e.g., chimneys, air conditioning units, vent pipes, and the like. The RGB data is again used to identify obstructions within the segments, i.e., objects that extend from the plane of a given segment. FIG. 8A through 8F depict roof image being processed to segment the roof using contour boundaries and using RGB data to determine obstructions. At 616, the method 600 applies the coordinates of the obstructions to the contour boundary defined segments. FIG. 8F depicts the planar segments and determined obstructions within the segments. At 618, the method 618 identifies useable roof segments as regions where planar segments exist without obstructions. The pixel coordinates of these regions and the original RGB image are further processed as described below to define the locations to place solar panels.

Once useable segments of the roof have been identified, computer vision algorithms are used for classifying different shapes and slopes on the segment surfaces and estimating of the number of panels that can be placed on the roof to meet the required energy production. This system is designed to give a near realistic assessment of how many panel arrays can be identified, with each useable segment given a rank depicting the energy harvesting capabilities and convenience of use, and also provide an estimate of how much energy each panel will produce when placed within a given segment. This system is designed for identifying contours for various types of houses, rooftops, and optimized for practical and aesthetically correct virtual panel placements.

Based upon the location of each contour segment and solar irradiance at the segment, every panel is ranked based on the highest practical possibility of harnessing solar energy. Energy production estimates and shading analysis are generated in real-time to determine a complete energy generation profile.

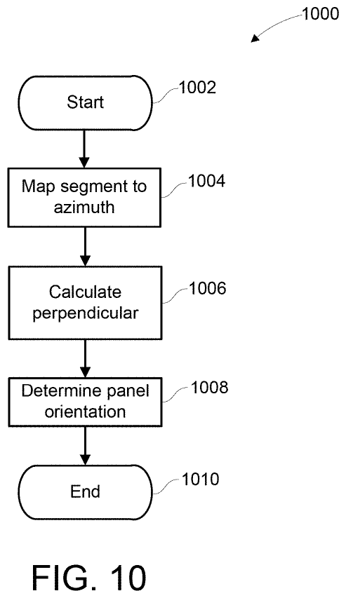

FIG. 9 depicts a flow diagram of a method 900 for prioritizing the locations to place solar panels on the roof image, orienting the solar panels to optimize the number of panels, and positioning the panels on the roof image. The method 900 begins at 902 and proceeds to 904 where solar azimuth angle is mapped to each useable segment that was defined in the method of FIG. 6. At 904, the method 900 determines a difference between the solar azimuth angle and a perpendicular line to the plane of the segment. This difference is a measure of the amount of energy that can be harvested by the panel. The closer the alignment between the perpendicular and the solar azimuth angle, the greater the amount of energy that is harvested (i.e., maximum harvest occurs when the sunlight angle of incidence upon the panel is perpendicular to the plane of the panel). Details of the process used to map the solar azimuth angle is described with reference to FIG. 10.

Using the azimuth map and irradiance data, at 906, the method 900 calculates the relative solar flux within each segment. To provide additional granularity for panel placement, the segments may be divided into subsegments. Details of the process used to calculate relative solar flux is described with reference to FIG. 12.

At 908, the method 900 calculates panel location priorities, i.e., which segments or subsegments provide the maximum amount of energy harvest potential. At 910, the method 900 identifies segments that contain pre-placed solar panels (i.e., existing solar panels). If there are solar panels currently on the roof, these portions of the roof must be avoided for placement of new panels. Such panels are identified as obstructions because they are offset above the plane of the roof, however, the obstruction is a large planar object and can be identified as a solar array. In some embodiments, the identification of pre-placed panels and/or placement of panels is accomplished by a machine learning algorithm (i.e., artificial intelligence) that is trained with examples of roofs and pre-placed solar panels. In one embodiment, a fully convolutional network, such as a U-Net architecture, may be used to identify pre-placed panels as well as other areas where panels should not be placed, i.e., porch roof. Such a system will improve its recognition of pre-placed panels and/or improve panel placement over time. The pre-placed panels also contribute to the overall energy production of the energy generation system and must be considered as part of the overall system. As such, their energy production is estimated in the same manner as the production from the newly placed solar panels.

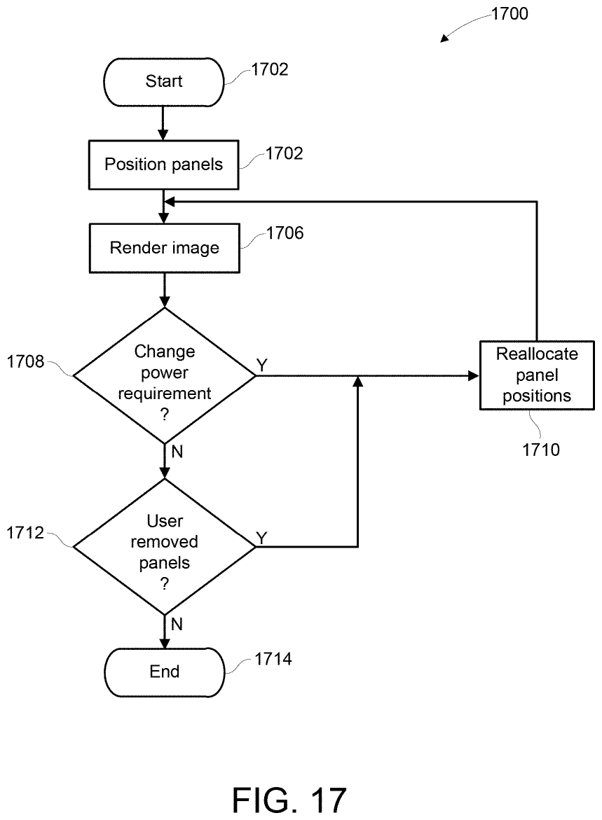

At 912, the method 900 positions solar panels and renders, in the user interface, an image of the roof with the panels positioned upon the roof (see FIG. 1). Details of the process used to position panels is described with reference to FIG. 17. At 914, the method 900 ends.

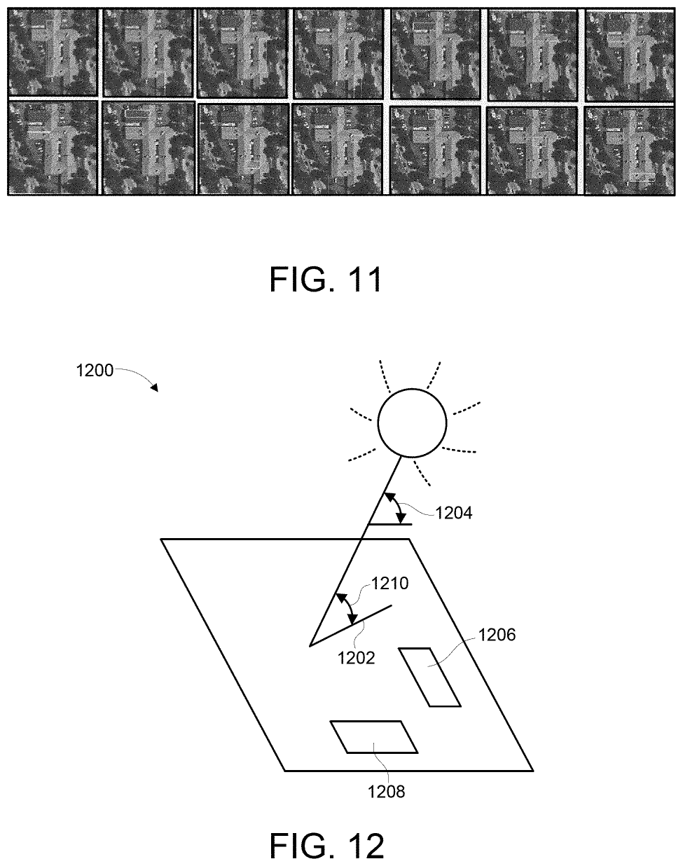

FIG. 10 depicts a flow diagram of a method 1000 for mapping a solar azimuth angle to each segment in accordance with an embodiment of the invention. The method 1000 starts at 1002 and proceeds to 1004 where each segment is mapped to a solar azimuth angle. In one embodiment, an average solar azimuth angle is used. In other embodiments, a solar azimuth angle at noon is used. FIG. 11 depicts a series of images where the azimuth angle is mapped segment by segment (e.g., within the white rectangular outline).

At 1006, the method 1000 calculates a perpendicular to each segment. At 1008, the method 1008 uses the solar azimuth angle and the perpendicular to determine the panel orientation (horizontal or vertical) that should be used for placing the panels in each segment. For example, if the perpendicular points east from a roof segment and the solar azimuth angle is from the south, panels in such a segment are best positioned horizontally across the segment. Alternatively, if the azimuth angle and the perpendicular both point in the same direction (e.g., south) then the panels are best positioned vertically. The offset difference between the perpendicular and the azimuth angle may be used to estimate the amount of energy that a given panel will be able to harvest (i.e., the closer the alignment of the perpendicular and the azimuth angle, the greater the amount of solar energy that will be harvested). The method ends at 1010.

FIG. 12 is a schematic graphical view of a segment 1200 showing the perpendicular 1202 and the solar azimuth angle 1204. The segment also contains a representation of the panel orientation—vertical 1206 and horizontal 1208. As described above, the selection of a particular panel orientation within a given segment depends on the direction and angle (1210) between the solar azimuth angle and the perpendicular to the segment.

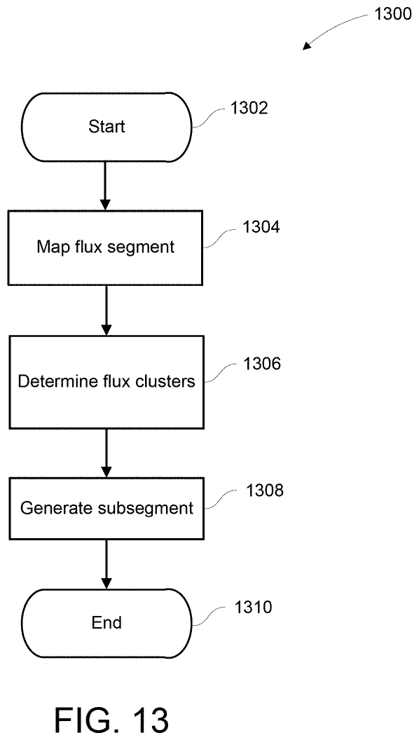

FIG. 13 depicts a flow diagram of a method 1300 for determining relative solar flux within a segment and using the flux to subsegment the segment in accordance with at least one embodiment of the invention. The method 1300 starts at 1302 and proceeds to 1304 where solar flux is mapped to each segment. The average amount of annual solar flux impinging on rooftops is available from, for example, Project Sunroof created by Google Inc and available at www.google.com/get/sunroof. The dataset has an irradiance value for each pixel within a rooftop. From this information, the method 1300 maps each irradiance value to a location within the segments.

At 1306, the method 1300 uses a clustering algorithm to determine flux clusters, i.e., regions within segments where the irradiance is substantially similar. Using the clusters, the method 1300, at 1308, generates subsegments of the segments. Each subsegment represents an area of the roof where the irradiance is substantially uniform. The method ends are 1310.

Note that areas of low irradiance (e.g., shadowed) will also be clustered and the next method will automatically avoid these areas for panel placement.

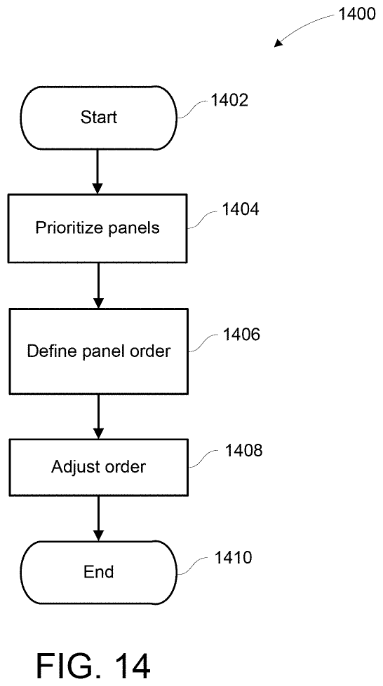

FIG. 14 depicts a flow diagram of a method 1400 for prioritizing panel placement in accordance with an embodiment of the invention. The method 1400 begins at 1402 and proceeds to 1404 where panels are initially prioritized based upon the level of irradiance in each subsegments. Thus, the highest priority locations for panels are the subsegments with the highest level of irradiance. At 1406, the order of panel placement is defined in accordance with the priority from 1404. At 1408, the order is adjusted based on the azimuth angle information from method 1000 of FIG. 10. For example, irradiance may be high within a particular subsegment, but the subsegment could be directed east when the solar azimuth angle is from the south. In that situation, the priority of panels in that particular subsegment may be demoted because those panels will not harvest a maximum amount of sunlight. Consequently, at 1408, each panel placement is reviewed to optimize the placement order and the order is adjusted. Also, areas with low irradiance will be given a low priority and will not be allocated any panels (i.e., no panels in shaded areas). The method ends at 1410.

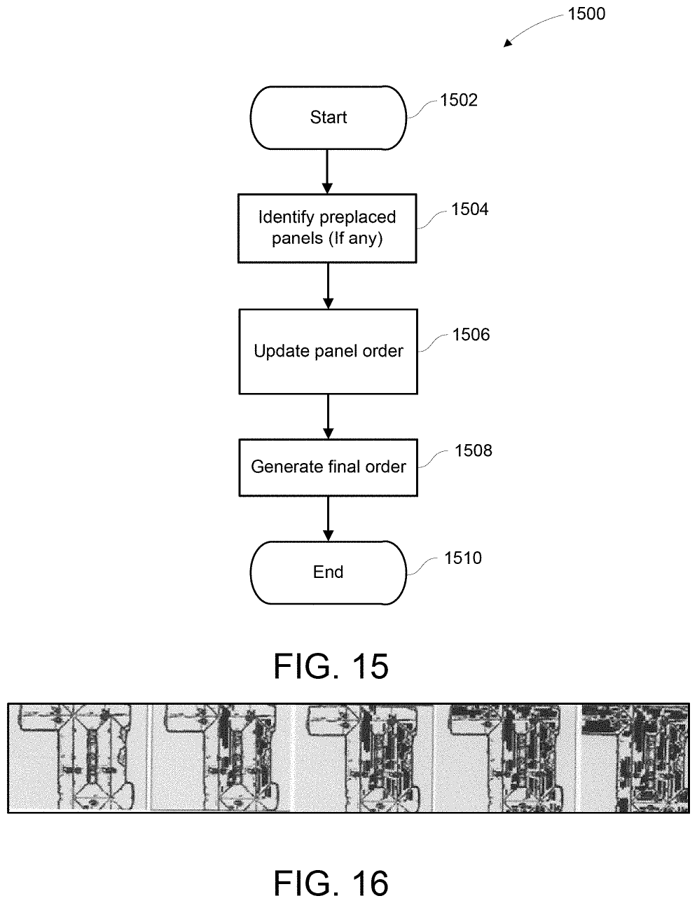

FIG. 15 depicts a flow diagram of a method 1500 for handling pre-placed panels in accordance with at least one embodiment of the invention. The method 1500 begins at 1502 and proceeds to 1504 where the method 1500 identifies pre-placed panels (if any). If there are solar panels currently on the roof, these portions of the roof must be avoided for placement of new panels. Such panels may be identified as obstructions because they are offset above the plane of the roof, however, the obstruction is a large planar object and can be identified as a solar array. In some embodiments, the identification of pre-placed panels and/or panel placement is accomplished by a machine learning algorithm (i.e., artificial intelligence) that is trained with examples of roofs and pre-placed solar panels. Such a system will improve its recognition of pre-placed panels and/or panel placement over time. The pre-placed panels also contribute to the overall energy production of the energy generation system and must be considered as part of the overall system. As such, their energy production is estimated in the same manner as the production from the newly placed solar panels.

If pre-placed panels are identified, at 1506, the method 1500 updates the panel placement order to avoid the region(s) where the pre-placed panels are located. At 1508, a final placement order is generated and the method 1500 ends at 1510.

FIG. 16 graphically depicts the panel placement order generation process. On the left is an image of a roof without any panels. As the methods 1400 and 1500 proceed, the roof is filled with solar panels (dark regions) as the methods progress from left to right images. In each subsegment, the panels are placed row-wise across the subsegment until the subsegment is covered with panels. Then the next priority subsegment is covered with panels, and so on until enough panels are placed to generate the amount of required energy.

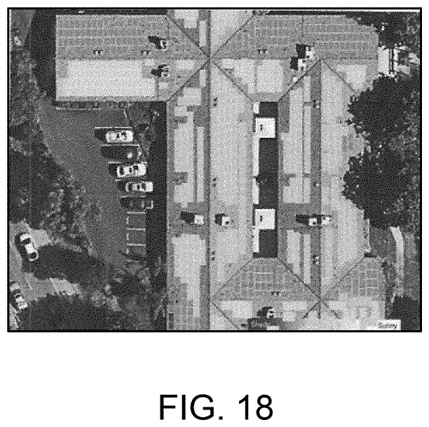

FIG. 17 depicts a flow diagram of a method 1700 for rendering an image of a roof containing optimally placed solar panels in accordance with an embodiment of the invention. The method 1700 begins at 1702 and proceeds to 1704 where panels fulfilling the required energy generation requirements are positioned using the final priority order of FIG. 15. At 1506, an image is rendered containing the panels. FIG. 18 depicts an embodiment of such a rendering. The panels (rectangles on the roof) are color coded to indicate which panels have the highest priority. In practice, the image is rendered at the user device. The original RGB satellite image is within the user interface and the server sends four x,y,z coordinates for the corners of each panel and the panel color to the user device. The user interface software then renders each panel in the proper location on the roof. On average, the complete computation of the component placement and rendering of an image requires approximately one minute.

The method 1700 continues at 1708 where the user may alter the energy generation requirement. The method 1700 queries at 1708 whether the power requirement has been changed. If the query is positively answered, the method 1700 proceeds to 1710 where the method 1700 must recalculate the number and placement of panels using methods 1400 (FIG. 14) and 1500 (FIG. 15) and then render the image again at 1706. Depending upon whether the power requirement was increased or decreased, the method 1700 will respectively increase or decrease the number of solar panels used to fulfill the power requirement.

If the query at 1708 is negatively answered, the method 1700 proceeds to 1712 where the method 1712 queries whether the user has removed panels. The user may interactively select (point with a mouse pointer and click) particular panels and have them removed from the rendered image. To indicate deselection, the selected panel changes color, e.g., changes to black to indicate removal. If one or more panels are removed and the query at 1712 is affirmatively answered, the method 1700 proceeds to 1710 where the number and location of the panels is recalculated. The recalculation, of course, takes into account the removed panels and will adjust the array to avoid the removed panel locations. The method 1700 proceeds to 1706 to render the updated roof image with altered panel placement. If the query at 1712 is negatively answered, the method 1700 ends at 1714.

FIG. 19 depicts a flow diagram of a method 1900 for placement of a storage system into a rendered image in accordance with an embodiment of the invention. The method 1900 begins at 1902 and proceeds to 1904 where the amount of storage required is determined. This requirement may be entered by a user or the value may be computed based on the generation capabilities of the energy generation system. At 1906, the method 1900 identifies storage devices that fulfill the storage requirements. For example, a system requiring 16 kWh of storage may require a single 10 kWh device, two 3 kWh devices and a switch to connect and disconnect the storage devices from the power system, as needed. Thus, the storage system may comprise 4 cabinets.

At 1908, the storage devices are positioned at a location within the facility. At 1910, the method 1900 renders an image (for example, FIG. 2) comprising the storage devices arranged upon a wall of the facility. As described above, the wall could be generated using the DSM data and the roof mask to determine the size and shape of exterior walls upon which the storage devices may be affixed. In other embodiments, a three-dimensional rendering of the facility may be developed or may be available from other sources such that a virtual storage device placement could be rendered within the three-dimensional rendering.

The method 1900 queries, at 1912, if any changes have been made to the storage requirements. If a change has been made, the method 1900 returns to 1904 to recompute the storage devices, their placement and the rendered image. If there are no changes, the method 1900 ends at 1914.

In other embodiments of the invention, the user could select a particular wall for the storage devices, or the system may select a wall and the user may change the location. Additional information could also be displayed with the rendered image such as the weight of the storage devices such that the user may determine if the selected wall will support the load.

The accuracy of the component placement system may be improved using machine learning to improve component placement through feedback of actual system designed by the system and then put into operation. Energy generation from actually systems may be used to train the algorithm and provide feedback on system design accuracy. Furthermore, in one or more embodiments, the system may use a regression testing mechanism where the algorithms' accuracy is calculated based on custom metrics defined by, one or more of, speed of algorithm, panels placed, segments detected, accuracy of placement, precision, recall and the like.

In further embodiments, street view imagery may be used to improve modelling of the facility as well as provide aesthetic views of the facility with components placement. A user could decide if the aesthetic view was acceptable or not.

In other embodiments, in lieu of using the energy estimates in a subsegment to prioritize panel positioning, the expected energy from each panel could be estimated to improve the accuracy of the overall panel placement. This per panel energy estimate could then be aggregated to provide a more accurate calculation of overall system power generation.

Here multiple examples have been given to illustrate various features and are not intended to be so limiting. Any one or more of the features may not be limited to the particular examples presented herein, regardless of any order, combination, or connections described. In fact, it should be understood that any combination of the features and/or elements described by way of example above are contemplated, including any variation or modification which is not enumerated, but capable of achieving the same. Unless otherwise stated, any one or more of the features may be combined in any order.

As above, figures are presented herein for illustrative purposes and are not meant to impose any structural limitations, unless otherwise specified. Various modifications to any of the structures shown in the figures are contemplated to be within the scope of the invention presented herein. The invention is not intended to be limited to any scope of claim language.

Where “coupling” or “connection” is used, unless otherwise specified, no limitation is implied that the coupling or connection be restricted to a physical coupling or connection and, instead, should be read to include communicative couplings, including wireless transmissions and protocols.

Any block, step, module, or otherwise described herein may represent one or more instructions which can be stored on a non-transitory computer readable media as software and/or performed by hardware. Any such block, module, step, or otherwise can be performed by various software and/or hardware combinations in a manner which may be automated, including the use of specialized hardware designed to achieve such a purpose. As above, any number of blocks, steps, or modules may be performed in any order or not at all, including substantially simultaneously, i.e., within tolerances of the systems executing the block, step, or module.

Where conditional language is used, including, but not limited to, “can,” “could,” “may” or “might,” it should be understood that the associated features or elements are not required. As such, where conditional language is used, the elements and/or features should be understood as being optionally present in at least some examples, and not necessarily conditioned upon anything, unless otherwise specified.

Where lists are enumerated in the alternative or conjunctive (e.g., one or more of A, B, and/or C), unless stated otherwise, it is understood to include one or more of each element, including any one or more combinations of any number of the enumerated elements (e.g. A, AB, AC, ABC, ABB, etc.). When “and/or” is used, it should be understood that the elements may be joined in the alternative or conjunctive.

While the foregoing is directed to embodiments of the present invention, other and further embodiments of the invention may be devised without departing from the basic scope thereof, and the scope thereof is determined by the claims that follow.

1. Apparatus for component placement for components of a system comprising an energy generation system, an energy storage system, or both comprising:
one or more processors coupled to one or more non-transitory computer readable media for storing instructions thereon which, when executed by the one or more processors, cause the one or more processors to perform operations comprising:
receiving indicium of a location for installation of the system;
receiving indicium of energy requirements for the facility at the location;
retrieving at least one image comprising one or more of a roof view of the facility, a digital surface map containing the facility or an irradiance map of the facility;
determining, based, at least in part, on one or more of the digital surface map or the irradiance map, locations for placement of components of the system; and
rendering an image of the facility including the components positioned at the determined locations.

2. The apparatus of claim 1 wherein, when the system comprises an energy generation system or an energy generation system and an energy storage system, the operations further comprise:
retrieving at least one image comprising one or more of a roof view of the facility, a digital surface map containing the facility and an irradiance map of the facility; and
determining, based, at least in part, on one or more of the digital surface map and the irradiance map, locations for placement of components of the system.

3. The apparatus of claim 1 wherein, when the system comprises an energy storage system, the operations further comprise:
retrieving at least one image comprising one or more of a roof view of the facility and a digital surface map containing the facility; and
determining, based, at least in part, on one or more of the digital surface map, locations for placement of components of the system.

4. The apparatus of claim 1 wherein the determining operation further comprises:
generating a roof mask comprising roof segments;
identifying obstructions within the roof segments; and
identifying roof segments having limited obstructions that are capable of supporting components.

5. The apparatus of claim 4 further comprising:
mapping a sun's azimuth to each roof segment;
calculating relative flux of each roof segment; and
positioning components based, at least in part, upon the relative flux of each roof segment.

6. The apparatus of claim 5 wherein some components are pre-placed.

7. The apparatus of claim 5 further comprising:
mapping a roof segment to the sun's azimuth;
calculating a perpendicular to the roof segment;
determining optimal energy generator orientation based, at least in part, upon a difference between the azimuth and the perpendicular.

8. The apparatus of claim 1 wherein the components of the energy generator system comprises a plurality of solar panels.

9. The apparatus of claim 1 further comprising:
enabling a user to alter placement of the components from the determined locations within the rendered image.

10. A method for component placement for components of a system including a solar energy generation system, an energy storage system or both comprising:
receiving indicium of a location for installation of the system;
receiving indicium of energy requirements for the facility at the location;
retrieving at least one image comprising one or more of a roof view of the facility, a digital surface map containing the facility or an irradiance map of the facility;
determining, based, at least in part, on one or more of the digital surface map or the irradiance map, locations for placement of components of the system; and
rendering an image of the facility including the components positioned at the determined locations.

11. The method of claim 10 wherein, when the system comprises an energy generation system or an energy generation system and an energy storage system, the method further comprises:
retrieving at least one image comprising one or more of a roof view of the facility, a digital surface map containing the facility and an irradiance map of the facility; and
determining, based, at least in part, on one or more of the digital surface map and the irradiance map, locations for placement of components of the system.

12. The method of claim 10 wherein, when the system comprises an energy storage system, the method further comprises
retrieving at least one image comprising one or more of a roof view of the facility and a digital surface map containing the facility; and
determining, based, at least in part, on one or more of the digital surface map, locations for placement of components of the system.

13. The method of claim 10 wherein determining further comprises:
generating a roof mask comprising roof segments;
identifying obstructions within the roof segments; and
identifying roof segments having limited obstructions that are capable of supporting the components.

14. The method of claim 13 further comprising:
mapping a sun's azimuth to each roof segment;
calculating relative flux of each roof segment; and
positioning components based, at least in part, upon the relative flux of each roof segment.

15. The method of claim 14 wherein some components are pre-placed.

16. The method of claim 14 further comprising:
mapping a roof segment to the sun's azimuth;
calculating a perpendicular to the roof segment;
determining optimal energy generator orientation based, at least in part, upon a difference between the azimuth and the perpendicular.

17. The method of claim 10 wherein the components of the energy generator system comprises a plurality of solar panels.

18. The method of claim 10 further comprising:
enabling a user to alter placement of the components from the determined locations within the rendered image.

19. A user interface for entering and displaying information regarding component placement for a system including an energy generation system, an energy storage system, or both comprising:
a field for entry of an indicium of a location for installation of the system;
a field for entry of an indicium of energy requirements; and
a region comprising a rendered image of the facility having the components positioned in locations determined from at least one image comprising a roof view of the facility, a digital surface map containing the facility, an irradiance map of the facility based, at least in part, upon the indicium of location.

20. The user interface of claim 19 wherein the components are solar panels.
